(19) United States
(12) Patent Application Publication
(10) Pub. No.: US 2014/0085855 A1
(43) Pub. Date: Mar. 27, 2014

(54) ELECTRONIC DEVICE

(71) Applicant: HON HAI PRECISION INDUSTRY CO., LTD., New Taipei (TW)

(72) Inventors: WEI-CHING CHIEN, New Taipei (TW); MENG-FENG KUO, New Taipei (TW)

(73) Assignee: HON HAI PRECISION INDUSTRY CO., LTD., New Taipei (TW)

(21) Appl. No.: 13/961,890

(22) Filed: Aug. 8, 2013

(30) Foreign Application Priority Data
Sep. 21, 2012 (TW) 101134815

(51) Int. Cl. H05K 7/02

(52) U.S. Cl. CPC H05K 7/023
USPC 361/803

(57) ABSTRACT

An electronic device includes a first circuit board, a second circuit board, and a third circuit board. A plurality of loads are mounted on the first circuit board, a plurality of direct current (DC) to DC converters are mounted on the second circuit board, and an alternating current (AC) to DC converter is mounted on the third circuit board. The first circuit board is electrically connected to the second circuit board, the DC to DC converters are configured to convert an input DC voltage from the third circuit board to a plurality of output DC voltages correspondingly, and the output DC voltages power the loads correspondingly. The electronic device separates the voltage-conversion processes from other working components, thus the electronic device is protected from electromagnetic interference.

### BACKGROUND

1. Technical Field

The disclosed embodiments relate to electronic devices, and particularly, to an electronic device with direct SDurrent (DC) to DC converters.

2. Description of Related Art

Generally, electronic devices, such as televisions, notebook computers, include a power converter and a plurality of loads. The plurality of loads can include a processor, a speaker, a universal serial bus (USB) connector, an earphone connector, and the like. The power converter converts an input alternating current (AC) voltage to an output direct current (DC) voltage. The output DC voltage powers the loads.

However, electromagnetic interference (EMI) may occur when the power converter converts the input AC voltage to the output DC voltage. Because the power converter and the loads are mounted on a same circuit board, EMI may affect the performance of the loads.

Therefore, there is room for improvement in the art.

### BRIEF DESCRIPTION OF THE DRAWINGS

Many aspects of the embodiments can be better understood with reference to the drawing. The components in the drawing are not necessarily drawn to scale, the emphasis instead being placed upon clearly illustrating the principles of the present embodiments. Moreover, in the drawings, like reference numerals designate corresponding parts throughout three views.

FIG. 1 is an exploded view showing an electronic device in accordance with one embodiment.

FIG. 2 is an assembled view of the electronic device in FIG. 1.

FIG. 3 is a block diagram of the electronic device in FIG. 1.

### DETAILED DESCRIPTION

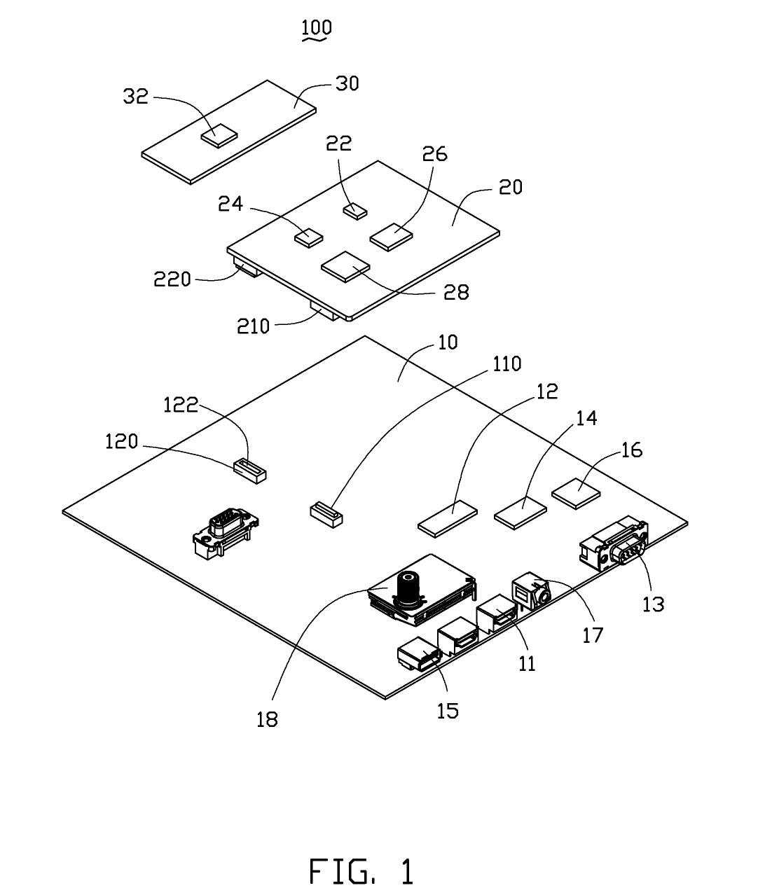

FIG. 1 shows an electronic device 100 in accordance with one embodiment. The electronic device 100 includes a first circuit board 10, a plurality of loads 11, 13, 15, 17, 18, 12, 14, and 16; a second circuit board 20, and a plurality of direct current (DC) to DC converters 22, 24, 26, and 28. In this embodiment, the electronic device 100 is a television.

The loads 11, 13, 15, 17, 18, 12, 14, and 16 are mounted on the first circuit board 10. In the embodiment, the load 11 is a high definition multimedia interface (HDMI) connector. The load 13 is a video graphic array (VGA) connector. The load 15 is a universal serial bus (USB) connector. The load 17 is an earphone connector. The load 18 is a tuner having an input port for receiving television signals. The load 12 is a processor. The load 14 is a demodulator. The load 16 is a decoder.

The DC to DC converters 22, 24, 26, and 28 are mounted on the second circuit board 20. The DC to DC converters 22, 24, 26, and 28 convert an input DC voltage to a plurality of output DC voltages correspondingly. The first circuit board 10 is electrically connected to the second circuit board 20. For example, the first circuit board 10 is electrically connected to the second circuit board 20 through wires (not shown). Therefore, the output DC voltages power the loads 11, 13, 15, 17, 18, 12, 14, and 16 correspondingly.

In detail, the electronic device 100 further includes a first male connector 110, a first female connector 210, a second male connector 220, a second female connector 120. The first male connector 110 and the second female connector 120 are mounted on the first circuit board 10, the first female connector 210 and the second male connector 220 are mounted on the second circuit board 20. The first male connector 110 is parallel to the second female connector 120, and the first female connector 210 is parallel to the second male connector 220. The number of pins of the first male connector 110 is not equal to the number of pins of the second male connector 220.

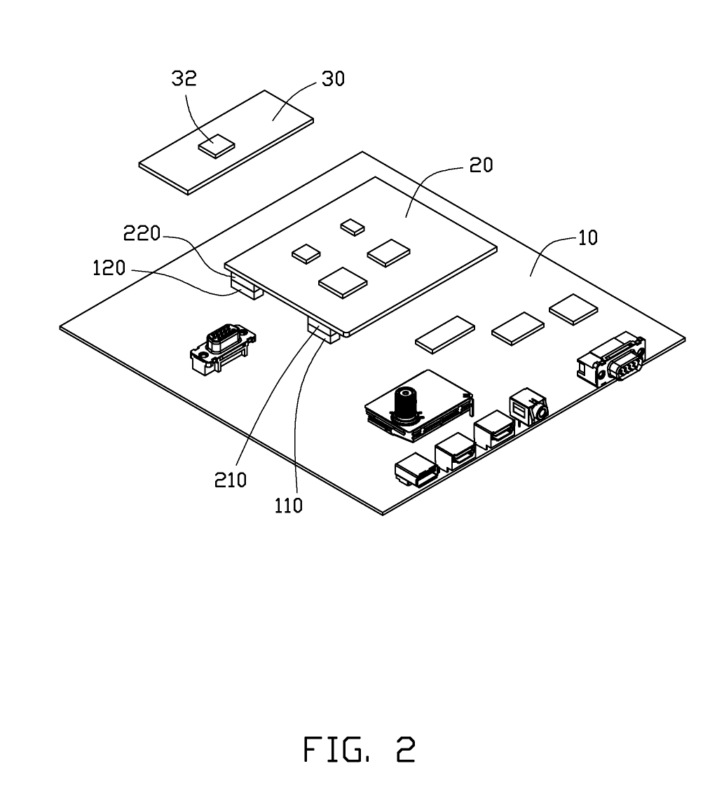

Referring to FIG. 2, the first male connector 110 couples with the first female connector 210, and the second male connector 220 couples with the second female connector 120.

The loads 12, 14, and 16 are defined as first loads, each first load is an integrated circuit (IC) chip. The loads 11, 13, 15, 17, and 18 are defined as second loads, each second load is an interface circuit. In other embodiments, the number of the first loads is one, and the number of the second loads is one.

The DC to DC converters 22, 24, 26, and 28 include a plurality of first DC to DC converters, such as 22 and 24 (that is, two first DC to DC converters), and a plurality of second DC to DC converters, such as 26 and 28 (that is, two second DC to DC converters). In other embodiments, the number of the first DC to DC converters is one or more than two, the number of the second DC to DC converters is one or more than two.

Each first DC to DC converter is a switchable DC to DC converter, each second DC to DC converter is a linear DC to DC converter. The output DC voltages comprise a plurality of first output DC voltages generated by the first DC to DC converters correspondingly and a plurality of second output DC voltages generated by the second DC to DC converters correspondingly.

The first output DC voltages power the first loads 12, 14, and 16 through the first female connector 210 and the first male connector 110 correspondingly, the second output DC voltages power the second loads 11, 13, 15, 17, and 18 through the second male connector 220 and the second female connector 120 correspondingly.

Furthermore, the electronic device 100 further includes a third circuit board 30 and an alternating current (AC) to DC converter 32. The AC to DC converter 32 is mounted on the third circuit board 30. The AC to DC converter 32 is electrically connected to the DC to DC converters 22, 24, 26, and 28, for example, through wires (not shown). The AC to DC converter 32 is configured to convert an input AC voltage to the input DC voltage, and the input DC voltage is transmitted to the DC to DC converters 22, 24, 26, and 28.

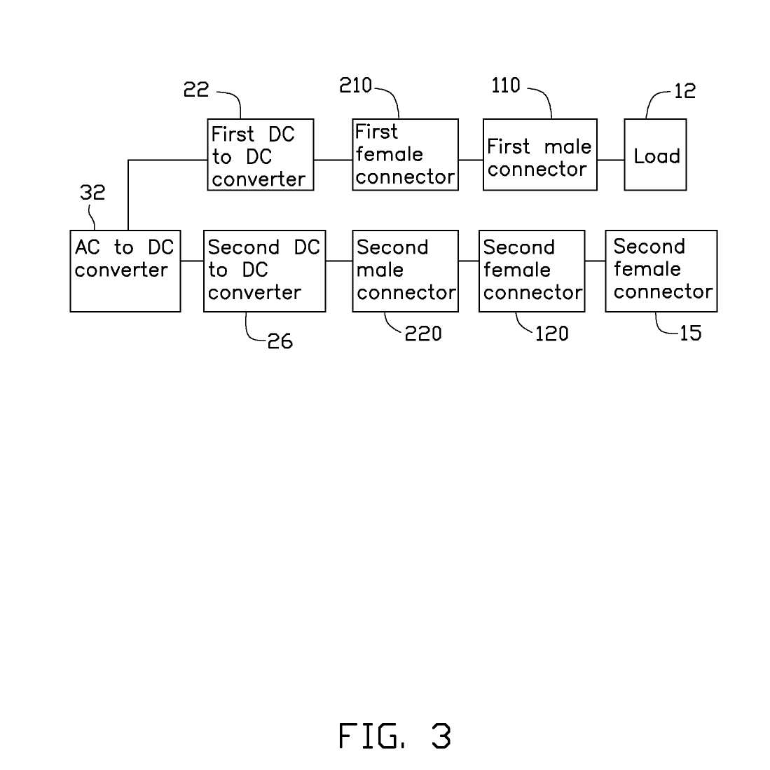

For example, as shown in FIG. 3, the first DC to DC converter 22 converts the input DC voltage from the AC to DC converter 32 to the first output DC voltage, and the first output DC voltage powers the first load 12 through the first female connector 210 and the first male connector 110. The second DC to DC converter 26 converts the input DC voltage from the AC to DC converter 32 to the second output DC voltage, and the second output DC voltage powers the second load 15 through the second male connector 220 and the second female connector 120.

In the electronic device 100, the AC to DC converter 32 is mounted on the third circuit board 30, the DC to DC converters 22, 24, 26, and 28 are mounted on the second circuit board 20, and the loads 11, 13, 15, 17, 18, 12, 14, and 16 are mounted on the first circuit board 10. Because the locational independence of the AC to DC converter 32, the DC to DC converters 22, 24, 26, and 28, and the loads 11, 13, 15, 17, 18, 12, 14, and 16 in not being mounted on the same circuit board, electromagnetic interference (EMI) to the loads 11, 13, 15, 17, 18, 12, 14, and 16 due to the process of voltage conversion in the AC to DC converter 32 and the DC to DC converters 22, 24, 26, and 28 is effectively reduced, as compared to the prior art.

Alternative embodiments will become apparent to those skilled in the art without departing from the spirit and scope of what is claimed. Accordingly, the present disclosure should not be deemed to be limited to the above detailed description, but rather only by the claims that follow and the equivalents thereof.

What is claimed is:

1. An electronic device, comprising:
a first circuit board;
a second circuit board;
a plurality of loads mounted on the first circuit board; and
a plurality of direct current (DC) to DC converters mounted on the second circuit board; wherein the first circuit board is electrically connected to the second circuit board, the DC to DC converters are configured to convert an input DC voltage to a plurality of output DC voltages correspondingly; the output DC voltages power the loads correspondingly.

2. The electronic device of claim 1, further comprising:
a first male connector;
a first female connector;
a second male connector; and
a second female connector;
wherein the first male connector mates with the first female connector; the second male connector mates with the second female connector; the DC to DC converters comprise a plurality of first DC to DC converters and a plurality of second DC to DC converters, the loads comprise a plurality of first loads and a plurality of second loads;
wherein the output DC voltages comprise a plurality of first output DC voltages generated by the first DC to DC converters correspondingly and a plurality of second output DC voltages generated by the second DC to DC converters correspondingly; the first output DC voltages power the first loads correspondingly through the first female connector and the first male connector; and
wherein the second output DC voltages power the second loads correspondingly through the second male connector and the second female connector.

3. The electronic device of claim 2, wherein the first male connector and the second female connector are mounted on the first circuit board, the first female connector and the second male connector are mounted on the second circuit board.

4. The electronic device of claim 2, wherein the first circuit board comprises a first surface, the loads and the first male connector and the second female connector are mounted on the first surface, the second circuit board comprises a second surface and a third surface, the DC to DC converters are mounted on the second surface, the first female connector and the second male connector are mounted on the third surface.

5. The electronic device of claim 2, wherein each of the first DC to DC converters is a switchable DC to DC converter, each of the second DC to DC converters is a linear DC to DC converter.

6. The electronic device of claim 1, further comprising a third circuit board and an alternating current (AC) to DC converter mounted on the third circuit board, wherein the AC to DC converter is electrically connected to the DC to DC converters, the AC to DC converter is configured to convert an input AC voltage to the input DC voltage.

7. The electronic device of claim 2, wherein the first male connector is parallel to the second female connector, and the first female connector is parallel to the second male connector.

8. The electronic device of claim 2, wherein a number of pins of the first male connector is not equal to the number of pins of the second male connector.

9. The electronic device of claim 2, wherein the first loads comprise a processor, a demodulator, and a decoder, the second loads comprise a tuner having an input port for receiving television signals, a high definition multimedia interface (HDMI) connector, a video graphic array (VGA) connector, an earphone connector, and a universal serial bus (USB) connector.

10. An electronic device, comprising:
a first circuit board;
a second circuit board;
at least one first load and at least one second load mounted on the first circuit board; and
at least one first DC to DC converter and at least one second DC to DC converter mounted on the second circuit board;
wherein the first circuit board is electrically connected to the second circuit board, the at least one first DC to DC converter is configured to convert an input DC voltage to a first output DC voltage, the first output DC voltage powers the at least one first load, the at least one second DC to DC converter is configured to convert the input DC voltage to a second output DC voltage, the second output DC voltage powers the at least one second load.

11. The electronic device of claim 10, further comprises:
a first male connector;
a first female connector;
a second male connector; and
a second female connector;
wherein the first male connector and the second female connector are mounted on the first circuit board, the first female connector and the second male connector are mounted on the second circuit board; the first male connector mates with the first female connector; the second male connector mates with the second female connector; the first output DC voltage powers at least one first load through the first female connector and the first male connector, the second output DC voltage powers at least one second load through the second male connector and the second female connector.

12. The electronic device of claim 11, wherein the first circuit board comprises a first surface; at least one first load, at least one second load, the first male connector and the second female connector are mounted on the first surface, the second circuit board comprises a second surface and a third surface, at least one first DC to DC converter and at least one second DC to DC converter are mounted on the second surface, the first female connector and the second male connector are mounted on the third surface.

13. The electronic device of claim 10, wherein at least one first DC to DC converter is a switchable DC to DC converter, at least one second DC to DC converter is a linear DC to DC converter.

14. The electronic device of claim 10, further comprising a third circuit board and an alternating current (AC) to DC converter mounted on the third circuit board, wherein the AC to DC converter is electrically connected to at least one first DC to DC converter and at least one second DC to DC converter, the AC to DC converter is configured to convert an input AC voltage to the input DC voltage.

15. The electronic device of claim 11, wherein the first male connector is parallel to the second female connector, and the first female connector is parallel to the second male connector.

16. The electronic device of claim 11, wherein a number of pins of the first male connector is not equal to the number of pins of the second male connector.

17. The electronic device of claim 10, wherein at least one first load is an integrated circuit (IC) chip, at least one second load is an interface circuit.

18. The electronic device of claim 10, wherein at least one first load comprises a processor, a demodulator, and a decoder; at least one second load comprises a tuner having an input port for receiving television signals, a high definition multimedia interface (HDMI) connector, a video graphic array (VGA) connector, an earphone connector, and a universal serial bus (USB) connector.
